(19) United States
(12) Patent Application Publication
(10) Pub. No.: US 2011/0146794 A1
(43) Pub. Date: Jun. 23, 2011

(54) THIN-FILM SOLAR CELL AND MANUFACTURE METHOD THEREOF

(75) Inventor: Chin-Yao Tsai, Tainan (TW)

(73) Assignee: AURIA SOLAR CO., LTD., Tainan (TW)

(21) Appl. No.: 13/038,536

(22) Filed: Mar. 2, 2011

(30) Foreign Application Priority Data
Mar. 17, 2010 (TW) 099107834
Mar. 17, 2010 (TW) 099107836

(51) Int. Cl. H01L 31/0232; H01L 31/18

(52) U.S. Cl. 136/259; 438/69; 257/E31.126

(57) ABSTRACT

A thin-film solar cell and a manufacture method thereof are provided. The thin-film solar cell comprises a transparent substrate, a first transparent conductive layer, a photovoltaic layer, a second transparent conductive layer and a light reflecting structure. The transparent substrate has a light incident surface and a back surface opposite to the light incident surface. The first transparent conductive layer is disposed on the back surface of the transparent substrate. The photovoltaic layer is disposed on the first transparent conductive layer. The second transparent conductive layer is disposed on the photovoltaic layer. The light reflecting structure is disposed on the second transparent conductive layer. The manufacture method forms the light reflecting structure having a texture structure on the thin film to enhance utilization of light beams in the thin-film solar cell so as to further improve photoelectric conversion efficiency of the thin-film solar cell.

This application claims priority to Taiwan Patent Applications No. 099107834 and No. 099107836 filed on Mar. 17, 2010, which are hereby incorporated by reference in their entirety.

### CROSS-REFERENCES TO RELATED APPLICATIONS

Not applicable.

### BACKGROUND OF THE INVENTION

1. Field of the Invention

The present invention relates to a solar cell and a manufacturing method thereof, and more particularly, to a thin-film solar cell with improved photoelectric conversion efficiency and a manufacturing method thereof.

2. Descriptions of the Related Art

Due to shortage of fossil energy resources and enhanced awareness of environmental protection, great efforts have been made continuously in recent years on development and research of technologies related to alternative energy resources and renewable energy resources. This is intended to reduce the level of dependence on fossil energy resources and influence of consumption of fossil energy resources on the environment. Among various technologies related to alternative energy resources and renewable energy resources, the solar cell has received the most attention. This is mainly because that the solar cell can convert the solar energy directly into the electric energy without emission of hazardous materials that may pollute the environment such as carbon dioxide or nitrides during electric power generation.

Generally, a conventional thin-film solar cell is typically formed by sequentially stacking an electrode layer, a photoelectric conversion layer and an electrode layer throughout a substrate. When light rays from the outside impinge on the thin-film solar cell, the photoelectric conversion layer irradiated by the light rays is adapted to generate free electron-hole pairs. Under action of a built-in electric field formed by the PN junction, the electrons and the holes migrate towards the two electrode layers respectively to result in an electric energy storage status. Then, if a load circuit or an electronic device is externally connected across the solar cell, the electric energy can be supplied to drive the load circuit or the electronic device.

However, thin-film solar cells currently available have photoelectric conversion efficiency as low as about 6%˜10% on average, and currently there still exists a bottleneck in improving the photoelectric conversion efficiency of the thin-film solar cells. Accordingly, efforts still have to be made in the art to provide a solution that can improve the photoelectric conversion efficiency of the thin-film solar cells.

### SUMMARY OF THE INVENTION

The present invention provides a thin-film solar cell, which can enhance the utilization factor of light beams to improve the photoelectric conversion efficiency of the thin-film solar cell.

The thin-film solar cell of the present invention comprises a transparent substrate, a first transparent conductive layer, a photovoltaic layer, a second transparent conductive layer and a light reflecting structure. The transparent substrate has a light incident surface and a light exiting surface opposite to the light incident surface. The first transparent conductive layer is disposed on the light exiting surface of the transparent substrate. The photovoltaic layer is disposed on the first transparent conductive layer. The second transparent conductive layer is disposed on the photovoltaic layer. The light reflecting structure is disposed on the second transparent conductive layer, wherein a light beam enters the thin-film solar cell via the light incident surface, passes sequentially through the transparent substrate, the first transparent conductive layer, the photovoltaic layer and the second transparent conductive layer and then into the light reflecting structure, and the light reflecting structure reflects the light beam.

In an embodiment of the present invention, the light reflecting structure comprises a patterned structure. The patterned structure has a first sub-pattern structure and a second sub-pattern structure. The first sub-pattern structure is disposed on the second transparent conductive layer, the second sub-pattern structure is disposed on the first sub-pattern structure, and the second sub-pattern structure at least partially overlaps the first sub-pattern structure.

In an embodiment of the present invention, the patterned structure may be of a straight stripe form, a stripe form, a transverse stripe form, a check form, a rhombus form, a honeycomb form or a mosaic form.

In an embodiment of the present invention, a surface where the first sub-pattern structure makes contact with the second transparent conductive layer is a texture structure.

In an embodiment of the present invention, at least a surface where the second sub-pattern structure makes contact with the first sub-pattern structure is a texture structure.

In an embodiment of the present invention, the light reflecting structure is a light reflecting structure layer, and the light reflecting structure layer is integrally formed.

In an embodiment of the present invention, the light reflecting structure layer entirely or partially covers the second transparent conductive layer.

In an embodiment of the present invention, a surface where the light reflecting structure layer makes contact with the second transparent conductive layer is a texture structure.

In an embodiment of the present invention, the light reflecting structure is made of one or more materials selected from a group consisting of a white paint, a metal, a metal oxide and an organic material.

In an embodiment of the present invention, the metal is selected from a group consisting of aluminum (Al), scandium (Sc), titanium (Ti), vanadium (V), chromium (Cr), manganese (Mn), iron (Fe), cobalt (Co), nickel (Ni), copper (Cu), zinc (Zn), gallium (Ga), germanium (Ge), yttrium (Y), zirconium (Zr), niobium (Nb), molybdenum (Mo), technetium (Tc), ruthenium (Ru), rhodium (Rh), palladium (Pd), silver (Ag), cadmium (Cd), indium (In), tin (Sn), antimony (Sb), lanthanum (La), gadolinium (Gd), hafnium (Hf), tantalum (Ta), tungsten (W), rhenium (Re), osmium (Os), iridium (Ir), platinum (Pt), gold (Au), thallium (Tl), lead (Pb) and alloys thereof.

In an embodiment of the present invention, the metal oxide comprises an indium oxide, a tin oxide, a silicon oxide, a magnesium fluoride, a tantalum oxide, a titanium oxide, a magnesium oxide, a zirconium oxide, a silicon nitride, an aluminum oxide, a hafnium oxide, a indium tin oxide (ITO), a cadmium stannate (Cd2SnO4), a cadmium stannate doped with copper, a stannic oxide or a stannic oxide doped with fluorine.

In an embodiment of the present invention, the organic material comprises a dye or a pigment.

In an embodiment of the present invention, a part of the light beam comprises a red light, a near infrared (IR) light or a far IR light.

In an embodiment of the present invention, the photovoltaic layer is a group IV element thin film, a group III-V compound semiconductor thin film, a group II-VI compound semiconductor thin film, an organic compound semiconductor thin film or a combination thereof.

In an embodiment of the present invention, the group IV element thin film comprises at least one of an a-Si thin film, a μc-Si thin film, an a-SiGe thin film, a μc-SiGe thin film, an a-SiC thin film, a μc-SiC thin film, a tandem group IV element thin film or a triple group IV element thin film.

In an embodiment of the present invention, the group III-V compound semiconductor thin film comprises gallium arsenide (GaAs), indium gallium phosphide (InGaP) or a combination thereof.

In an embodiment of the present invention, the group II-VI compound semiconductor thin film comprises copper indium selenium (CIS), copper indium gallium selenium (CIGS), cadmium telluride (CdTe) or a combination thereof.

In an embodiment of the present invention, the organic compound semiconductor thin films comprise a mixture of poly(3-hexylthiophene) (P3HT) and carbon nanospheres (PCBM).

In an embodiment of the present invention, the transparent substrate is a glass substrate.

According to the above descriptions, the thin-film solar cell of the present invention has a light reflecting structure disposed on the second transparent conductive layer to increase the opportunity for the light beam to be reflected in the thin-film solar cell. This can prolong the light path of the light beam in the photovoltaic layer so that the light beam will be more likely absorbed by the photovoltaic layer to generate more electron-hole pairs. In other words, the thin-film solar cell employing the light reflecting structure can effectively enhance the utilization factor of the light beam to improve the photoelectric conversion efficiency thereof.

The present invention also provides a method for manufacturing a thin-film solar cell, which can form a light reflecting structure having a texture structure on a layer. This can enhance the utilization factor of the light beam in the thin-film solar cell, thus resulting in improved photoelectric conversion efficiency of the thin-film solar cell.

The method for manufacturing a thin-film solar cell of the present invention comprises the following steps of: providing a transparent substrate; forming a first transparent conductive layer on the transparent substrate; forming a photovoltaic layer on the first transparent conductive layer; forming a second transparent conductive layer on the photovoltaic layer; and forming a light reflecting structure having a texture structure on the second transparent conductive layer.

In an embodiment of the present invention, the light reflecting structure is formed through an impression process.

In an embodiment of the present invention, the impression process comprises: forming a reflective material layer on the second transparent conductive layer entirely; and impressing a mold with a texture pattern onto the reflective material layer to form the light reflecting structure having the texture structure.

In an embodiment of the present invention, the impression process comprises: forming a transparent material layer on the second transparent conductive layer entirely; impressing a mold with a texture pattern onto the transparent material layer to form the texture structure on the surface of the transparent material layer; and forming a reflective material layer on the transparent material layer.

In an embodiment of the present invention, the reflective material layer is conformal to the transparent material layer.

In an embodiment of the present invention, the impression process comprises: impressing a first sub-pattern structure on the second transparent conductive layer; and impressing a second sub-pattern structure on the first sub-pattern structure, wherein the second sub-pattern structure at least partially overlaps the first sub-pattern structure to form the light reflecting structure.

In an embodiment of the present invention, the light reflecting structure may be of a straight stripe form, a stripe form, a transverse stripe form, a check form, a rhombus form, a honeycomb form or a mosaic form.

In an embodiment of the present invention, the light reflecting structure is formed through a mesh process.

In an embodiment of the present invention, the mesh process comprises: disposing a mold having a mesh pattern on the second transparent conductive layer, wherein the mesh pattern has a plurality of openings exposing the second transparent conductive layer; forming a reflective material layer on the mold, wherein portions of the reflective material layer is filled into the openings to connect to the second transparent conductive layer; and removing the mold to form the light reflecting structure having the texture structure.

In an embodiment of the present invention, the mesh process comprises: forming a transparent material layer on the second transparent conductive layer entirely; impressing a mold with a mesh pattern onto the transparent material layer to form the mesh pattern on a surface of the transparent material layer; removing the mold; and forming a reflective material layer on the transparent material layer.

In an embodiment of the present invention, the mesh process comprises: disposing a first mold with a first mesh pattern on the second transparent conductive layer, wherein the first mesh pattern has a plurality of first openings exposing the second transparent conductive layer; forming a first sub-pattern structure on the first mold, wherein the first sub-pattern structure connects with portions of the second transparent conductive layer; disposing a second mold with a second mesh pattern on the first sub-pattern structure, wherein the second mesh pattern has a plurality of second openings exposing at least portions of the first openings; and forming a second sub-pattern structure on the first sub-pattern structure, wherein the second sub-pattern structure at least partially overlaps the first sub-pattern structure to form the light reflecting structure.

In an embodiment of the present invention, the organic material comprises a dye or a pigment.

In an embodiment of the present invention, the transparent substrate has a light incident surface, wherein a light beam enters the thin-film solar cell via the light incident surface, passes sequentially through the transparent substrate, the first transparent conductive layer, the photovoltaic layer and the second transparent conductive layer and then into the light reflecting structure. The light reflecting structure reflects the light beam.

In an embodiment of the present invention, the method for manufacturing a thin-film solar cell further comprises covering an adhesive layer on the light reflective structure to package a counter transparent substrate and the transparent substrate together.

According to the above descriptions, the method for manufacturing a thin-film solar cell of the present invention forms a light reflecting structure having a texture structure on the second transparent conductive layer to increase the opportunity for the light beam to be reflected in the thin-film solar cell. This can prolong the light path of the light beam in the photovoltaic layer so that the light beam will be more likely absorbed by the photovoltaic layer to generate more electron-hole pairs. In other words, the method for manufacturing a thin-film solar cell of the present invention can effectively enhance the utilization factor of the light beam in the resulting thin-film solar cell, thus improving the photoelectric conversion efficiency of the thin-film solar cell.

The detailed technology and preferred embodiments implemented for the subject invention are described in the following paragraphs accompanying the appended drawings for people skilled in this field to well appreciate the features of the claimed invention.

### BRIEF DESCRIPTION OF THE DRAWINGS

FIG. 1 is a schematic cross-sectional view of a thin-film solar cell according to an embodiment of the present invention;

FIGS. 2A to 2D are schematic top views of a light reflecting structure according to different embodiments of the present invention;

FIG. 3 is a schematic cross-sectional view of a thin-film solar cell according to another embodiment of the present invention;

FIG. 4 is a schematic cross-sectional view of a thin-film solar cell according to another embodiment of the present invention;

FIG. 5 is a schematic cross-sectional view of a thin-film solar cell according to another embodiment of the present invention;

FIG. 6 is a schematic cross-sectional view of a thin-film solar cell according to another embodiment of the present invention;

FIG. 7 is a schematic cross-sectional view of a thin-film solar cell according to another embodiment of the present invention;

FIGS. 8A to 8D are schematic cross-sectional views illustrating a manufacturing process of a thin-film solar cell according to an embodiment of the present invention;

FIGS. 9A to 9D are schematic cross-sectional views illustrating a manufacturing process of a thin-film solar cell according to another embodiment of the present invention;

FIGS. 10A to 10C are schematic cross-sectional views illustrating a manufacturing process of a thin-film solar cell according to another embodiment of the present invention;

FIGS. 11A and 11B are schematic cross-sectional views illustrating a manufacturing process of a thin-film solar cell according to another embodiment of the present invention;

FIGS. 12A to 12D are schematic cross-sectional views illustrating a manufacturing process of a thin-film solar cell according to another embodiment of the present invention;

FIGS. 13A to 13D are schematic cross-sectional views illustrating a manufacturing process of a thin-film solar cell according to another embodiment of the present invention; and

FIGS. 14A to 14E are schematic cross-sectional views illustrating a manufacturing process of a thin-film solar cell according to another embodiment of the present invention.

### DESCRIPTION OF THE PREFERRED EMBODIMENT

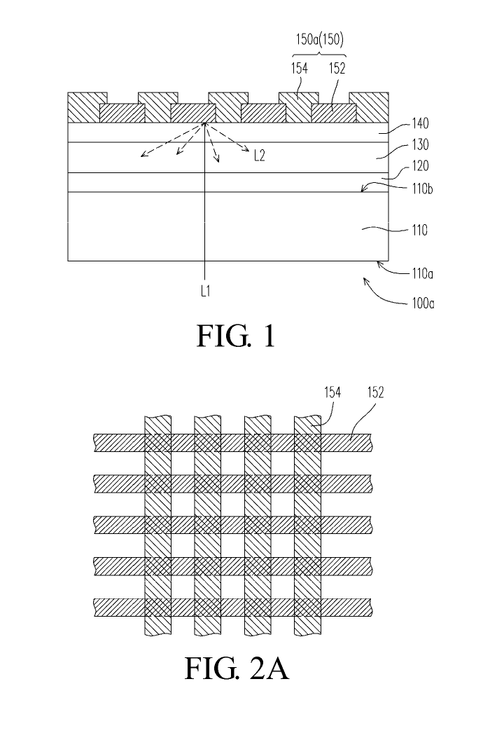

FIG. 1 is a schematic cross-sectional view of a thin-film solar cell according to an embodiment of the present invention. Referring to FIG. 1, in this embodiment, the thin-film solar cell 100a comprises a transparent substrate 110, a first transparent conductive layer 120, a photovoltaic layer 130, a second transparent conductive layer 140 and a light reflecting structure 150.

The transparent substrate 110 has a light incident surface 110a and a light exiting surface 110b opposite to the light incident surface 110a. The transparent substrate 110 is, for example, a glass substrate. The first transparent conductive layer 120 is disposed on the light exiting surface 110b of the transparent substrate 110. The photovoltaic layer 130 is disposed on the first transparent conductive layer 120. The second transparent conductive layer 140 is disposed on the photovoltaic layer 130. The light reflecting structure 150 is disposed on the second transparent conductive layer 140. A light beam L1 enters the thin-film solar cell 100a via the light incident surface 110a, passes sequentially through the transparent substrate 110, the first transparent conductive layer 120, the photovoltaic layer 130 and the second transparent conductive layer 140 and then into the light reflecting structure 150, and is reflected by the light reflecting structure 150.

Generally, the first transparent conductive layer 120 and the second transparent conductive layer 140 may both be made of a transparent conductive material such as indium tin oxide (ITO), indium zinc oxide (IZO), indium tin zinc oxide (ITZO), zinc oxide, aluminum tin oxide (ATO), aluminum zinc oxide (AZO), cadmium indium oxide (CIO), cadmium zinc oxide (CZO), gallium zinc oxide (GZO) and fluorine-doped tin oxide (FTO), or a combination thereof.

The photovoltaic layer 130 may be a group IV element thin film, a group III-V compound semiconductor thin film, a group II-VI compound semiconductor thin film, an organic compound semiconductor thin film or a combination thereof. In detail, the group IV element thin film comprises, for example, at least one of an a-Si thin film, a μc-Si thin film, an a-SiGe thin film, a μc-SiGe thin film, an a-SiC thin film, a μc-SiC thin film, a tandem group IV element thin film (e.g., a stacked silicon thin film) or a triple group IV element thin film. The group III-V compound semiconductor thin film comprises, for example, gallium arsenide (GaAs), indium gallium phosphide (InGaP) or a combination thereof. The group II-VI compound semiconductor thin film comprises, for example, copper indium selenium (CIS), copper indium gallium selenium (CIGS), cadmium telluride (CdTe) or a combination thereof. The organic compound semiconductor thin films comprise, for example, a mixture of poly(3-hexylthiophene) (P3HT) and carbon nanospheres (PCBM).

In other words, the thin-film solar cell 100a may adopt a layered structure of an amorphous silicon thin-film solar cell, a microcrystalline silicon thin-film solar cell, a tandem thin-film solar cell, a triple thin-film solar cell, a CIS thin-film solar cell, a CIGS thin-film solar cell, a CdTe thin-film solar cell or an organic thin-film solar cell. That is, depending on the user's design and requirements on the photovoltaic layer 130, the thin-film solar cell 100a of this embodiment may also be of other possible layered structures; and what described above is only for illustration purpose but is not to limit the present invention.

As shown in FIG. 1, the light reflecting structure 150 of this embodiment is, for example, a patterned structure 150a. The patterned structure 150a comprises a first sub-pattern structure 152 and a second sub-pattern structure 154. The first sub-pattern structure 152 is disposed on the second transparent conductive layer 140, and the second sub-pattern structure 154 is disposed on the first sub-pattern structure 152 and at least partially overlaps the first sub-pattern structure 152. That is, the second sub-pattern structure 154 only partially overlaps the first sub-pattern structure 152; in other words, portions of the second sub-pattern structure 154 is disposed on the second transparent conductive layer 140.

Specifically, after entering the thin-film solar cell 100a via the light incident surface 110a of the transparent substrate 110, the light beam L1 sequentially passes through the transparent substrate 110, the first transparent conductive layer 120 and the photovoltaic layer 130. A part of the light beam L1 that is unabsorbed by the photovoltaic layer 130 is then transmitted through the second transparent conductive layer 140 to the patterned structure 150a. Then, the first sub-pattern structure 152 and the second sub-pattern structure 154 of the patterned structure 150a can reflect a part L2 of the light beam L1 to the photovoltaic layer 130. In this embodiment, the light beam L2 is, for example, a red light, a near infrared (IR) light or a far IR light.

In other words, by using the stack structure formed by the first sub-pattern structure 152 and the second sub-pattern structure 154 to affect the propagation direction of the light beam L1, the light beam L1 is reflected at the interface between the patterned structure 150a and the second transparent conductive layer 140. Thus, the patterned structure 150a can increase the opportunity for the light beam L1 to be reflected in the thin-film solar cell 100a. This can prolong the light path of the light beam L1 in the photovoltaic layer 130 and, consequently, increase the opportunity for the light beam to be absorbed by the photovoltaic layer 130. As a result, the thin-film solar cell 100a can effectively utilize and absorb the light beam L1 and convert it into electric energy, thus resulting in higher photoelectric conversion efficiency.

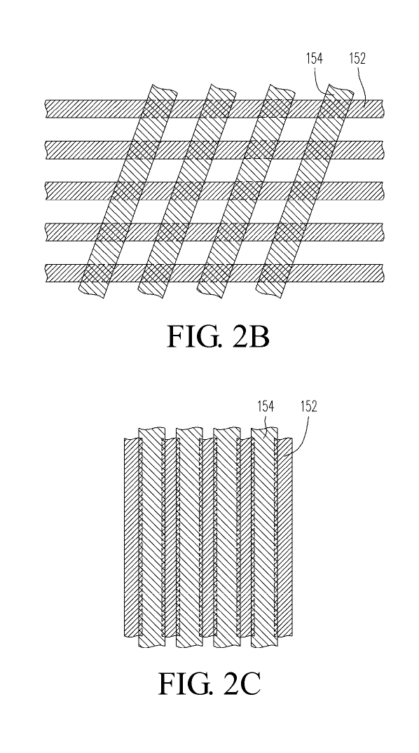

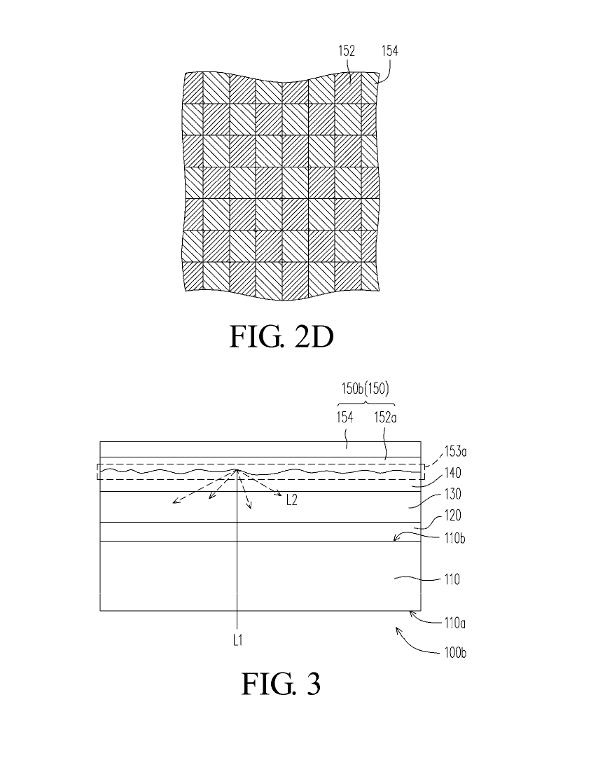

In this embodiment, by modifying the form of the patterned structure 150a or forming the light reflecting structure 150 of different materials, an objective of reflecting a part L2 of the light beam L1 can be achieved. Specifically, the patterned structure 150a of this embodiment is of, for example, a check form formed by orthogonal intersection of the first sub-pattern structure 152 and the second sub-pattern structure 154 as shown in FIG. 2A; a rhombus form formed by intersection of the first sub-pattern structure 152 and the second sub-pattern structure 154 at an angle as shown in FIG. 2B; a straight stripe form (shown in FIG. 2C), a regular or irregular stripe form (not shown) or a transverse stripe form (not shown) formed by parallel arrangement and partial overlapping between the first sub-pattern structure 152 and the second sub-pattern structure 154; or a mosaic form (shown in FIG. 2D) or a honeycomb form (not shown) formed through regular or irregular arrangement of the first sub-pattern structure 152 and the second sub-pattern structure 154. In other words, the arrangement and structures of the first sub-pattern structure 152 and the second sub-pattern structure 154 can be varied depending on the user's requirements; and what described above is only for illustration purpose but is not to limit the present invention.

Additionally, the light reflecting structure 150 may be made of one or more materials selected from a group consisting of a white paint, a metal, a metal oxide and an organic material. The metal is selected from a group consisting of aluminum (Al), scandium (Sc), titanium (Ti), vanadium (V), chromium (Cr), manganese (Mn), iron (Fe), cobalt (Co), nickel (Ni), copper (Cu), zinc (Zn), gallium (Ga), germanium (Ge), yttrium (Y), zirconium (Zr), niobium (Nb), molybdenum (Mo), technetium (Tc), ruthenium (Ru), rhodium (Rh), palladium (Pd), silver (Ag), cadmium (Cd), indium (In), tin (Sn), antimony (Sb), lanthanum (La), gadolinium (Gd), hafnium (Hf), tantalum (Ta), tungsten (W), rhenium (Re), osmium (Os), iridium (Ir), platinum (Pt), gold (Au), thallium (Tl), lead (Pb) and alloys thereof. The metal oxide may be selected from an indium oxide, a tin oxide, a silicon oxide, a magnesium fluoride, a tantalum oxide, a titanium oxide, a magnesium oxide, a zirconium oxide, a silicon nitride, an aluminum oxide, a hafnium oxide, a indium tin oxide (ITO), a cadmium stannate (Cd2SnO4), a cadmium stannate doped with copper, a stannic oxide or a stannic oxide doped with fluorine. The organic material may be a dye or a pigment.

Additionally, in an embodiment not shown, the patterned structure may also be a poly-layer formed by a plurality of first polymer materials and a plurality of second polymer materials alternately arranged. The first polymer materials are, for example, hydroxyl acetoxylated polyethylene terephthalate (PET) or a copolymer of hydroxyl acetoxylated polyethylene terephthalate, and the second polymer materials are, for example, polyethylene naphthalate (PEN) or a copolymer of polyethylene naphthalate. However, the materials described above are only provided as examples, and materials that can have the light reflecting structure 150 reflect the light beam all fall within the scope of the present invention.

Hereinbelow, designs of the thin-film solar cells 100b˜100f will be described with reference to several embodiments. It shall be appreciated herein that, some of the reference numerals and contents of the above embodiments apply also to the following embodiments, wherein identical reference numerals are used to denote the same or similar elements, and descriptions of identical technical contents will be omitted. For descriptions of the omitted portions, reference may be made to the aforesaid embodiments.

FIG. 3 is a schematic cross-sectional view of a thin-film solar cell according to another embodiment of the present invention. Referring to FIG. 1 and FIG. 3 together, the thin-film solar cell 100b of this embodiment is similar to the thin-film solar cell 100a of FIG. 1 except that: the light reflecting structure 150 of this embodiment is a patterned structure 150b, and a surface where the first sub-pattern structure 152a of the patterned structure 150b makes contact with the second transparent conductive layer 140 is, for example, a texture structure 153a. To be more specific, the patterned structure 150b of this embodiment covers the second transparent conductive layer 140 entirely, and the surface where the first sub-pattern structure 152 makes contact with the second transparent conductive layer 140 is the texture structure 153a which is, for example, a surface microstructure formed on the surface of the first sub-pattern structure 152a. Of course, in other embodiments not shown, the texture structure 153a may also be a surface microstructure formed on the surface of the second transparent conductive layer 140.

Because the surface where the patterned structure 150b makes contact with the second transparent conductive layer 140 is a texture structure 153a, it becomes easier for the light beam L1 propagating to the texture structure 153a to be reflected by the texture structure 153a and for the reflected light beam L2 to be scattered. This can prolong the light path of the light beam L2 in the photovoltaic layer 130 and, consequently, increase the opportunity for the light beam L2 to be absorbed by the photovoltaic layer 130, thus improving the overall photoelectric conversion efficiency. Furthermore, the part L2 of the light beam L1 can be reflected directly by the patterned structure 150b to the photovoltaic layer 130. In other words, the first sub-pattern structure 152a and the second sub-pattern structure 154 of the patterned structure 150b can affect the propagation direction of the light beam L1 in such a way that the light beam L1 is reflected and scattered by the surface where the first sub-pattern structure 152a makes contact with the second transparent conductive layer 140 or in such a way that the light beam L1 is reflected by the second patterned structure 154. In this way, the opportunity for the light beam L1 to be reflected in the thin-film solar cell 100b can be increased to prolong the light path of the light beam L1 in the photovoltaic layer 130 so that the light beam L1 will be more likely absorbed by the photovoltaic layer 130 to generate more electron-hole pairs. In other words, the thin-film solar cell 100b can effectively enhance the utilization factor of the light beam L1 to improve the photoelectric conversion efficiency.

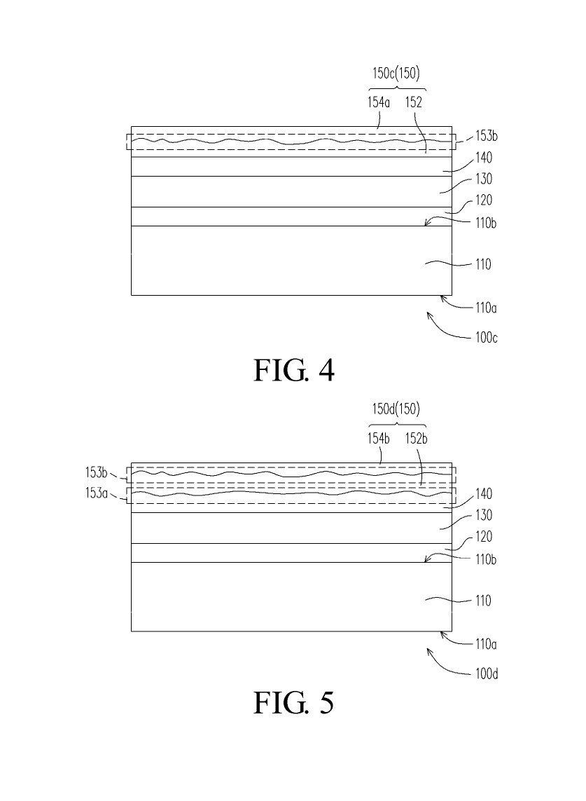

FIG. 4 is a schematic cross-sectional view of a thin-film solar cell according to another embodiment of the present invention. Referring to FIG. 3 and FIG. 4 together, the thin-film solar cell 100c of this embodiment is similar to the thin-film solar cell 100b of FIG. 3 except that: in this embodiment, a surface where the second sub-pattern structure 154b makes contact with the first sub-pattern structure 152 is a texture structure 153b which is, for example, a surface microstructure formed on the surface of the second sub-pattern structure 154a. Of course, in other embodiments not shown, the texture structure 153b may also be a surface microstructure formed on the surface of the first sub-pattern structure 152.

FIG. 5 is a schematic cross-sectional view of a thin-film solar cell according to another embodiment of the present invention. Referring to FIG. 3 and FIG. 5 together, the thin-film solar cell 100d of this embodiment is similar to the thin-film solar cell 100b of FIG. 3 except that: in this embodiment, a surface where the first sub-pattern structure 152b makes contact with the second transparent conductive layer 140 is, for example, a texture structure 153a, and a surface where the second sub-pattern structure 154b makes contact with the first sub-pattern structure 152b is a texture structure 153b. The texture structure 153a is, for example, a surface microstructure formed on the surface of the first sub-pattern structure 152b, and the texture structure 153b is, for example, a surface microstructure formed on the surface of the second sub-pattern structure 154b. Of course, in other embodiments not shown, the texture structure 153a may also be a surface microstructure formed on the surface of the second transparent conductive layer 140, and the texture structure 153b may also be a surface microstructure formed on the surface of the first sub-pattern structure 152b.

It shall be appreciated herein that, the present invention has no limitation on configurations of the patterned structures 150a˜150d. Although the patterned structures 150a˜150d set forth herein are described to have the first sub-pattern structures 152, 152a, 152b and the second sub-pattern structures 154, 154a, 154b (i.e., each of the patterned structures 150a˜150d consists of two layers of patterned structures), other designs capable of achieving the equivalent effect of reflecting a light beam (e.g., the patterned structure is a layer of continuous structure, a layer of discontinuous structure, a plurality of layers of continuous structures or a plurality of discontinuous structures) can also be adopted in the present invention without departing from the scope of the present invention.

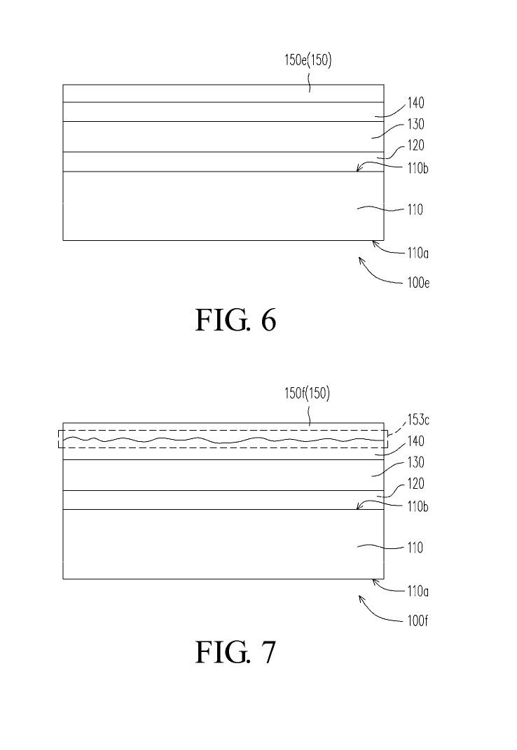

FIG. 6 is a schematic cross-sectional view of a thin-film solar cell according to another embodiment of the present invention. Referring to FIG. 1 and FIG. 6 together, the thin-film solar cell 100e of this embodiment is similar to the thin-film solar cell 100a of FIG. 1 except that, the light reflecting structure 150 of this embodiment is a light reflecting structure layer 150e and the light reflecting structure layer 150e is integrally formed. The light reflecting structure layer 150e covers the second transparent conductive layer 140 entirely to increase the opportunity for the light beam L1 to be reflected in the thin-film solar cell 100e. This can prolong the light path of the light beam L1 in the photovoltaic layer 130 so that the light beam L1 will be more likely absorbed by the photovoltaic layer 130 to generate more electron-hole pairs. In other words, the thin-film solar cell 100e can effectively enhance the utilization factor of the light beam L1 to improve the photoelectric conversion efficiency thereof.

It is worth noting that, the present invention has no limitation on configurations of the light reflecting structure layer 150e. Although the light reflecting structure layer 150e set forth herein is described to entirely cover the second transparent conductive layer 140, other designs capable of achieving the equivalent effect of reflecting a light beam (e.g., the light reflecting structure layer 150e only partially covers the second transparent conductive layer 140) can also be adopted in the present invention without departing from the scope of the present invention.

FIG. 7 is a schematic cross-sectional view of a thin-film solar cell according to another embodiment of the present invention. Referring to FIG. 6 and FIG. 7 together, the thin-film solar cell 100f of this embodiment is similar to the thin-film solar cell 100e of FIG. 6 except that: in this embodiment, a surface where the light reflecting structure layer 150f makes contact with the second transparent conductive layer 140 is a texture structure 153c which is, for example, a surface microstructure formed on the surface of the light reflecting structure layer 150f. Of course, in other embodiments not shown, the texture structure 153c may also be a surface microstructure formed on the surface of the second transparent conductive layer 140.

According to the above descriptions, the present invention has a light reflecting structure disposed on the second transparent conductive layer to increase the opportunity for the light beam to be reflected in the thin-film solar cell. This can prolong the light path of the light beam in the photovoltaic layer so that the light beam will be more likely absorbed by the photovoltaic layer to generate more electron-hole pairs. In other words, the thin-film solar cell employing the light reflecting structure can effectively enhance the utilization factor of the light beam to improve the photoelectric conversion efficiency thereof. Furthermore, through design of the texture structure, the light beam can be reflected and scattered to the photovoltaic layer to prolong the light path of the light beam in the photovoltaic layer; this also increases the opportunity for the light beam to be absorbed by the photovoltaic layer to improve the overall photoelectric conversion efficiency.

Hereinbelow, methods for manufacturing a thin-film solar cell will be described with reference to several different embodiments. It shall be appreciated herein that, the following embodiments are intended to disclose methods for manufacturing the aforesaid thin-film solar cells, so some of the reference numerals and contents of the above embodiments will also apply to the following embodiments; in terms of this, identical reference numerals will be used to denote the same or similar elements, and descriptions of identical technical contents (including descriptions of materials of elements, shapes of the elements and how the elements are connected) will be omitted. For descriptions of the omitted portions, reference may be made to the aforesaid embodiments of the thin-film solar cell.

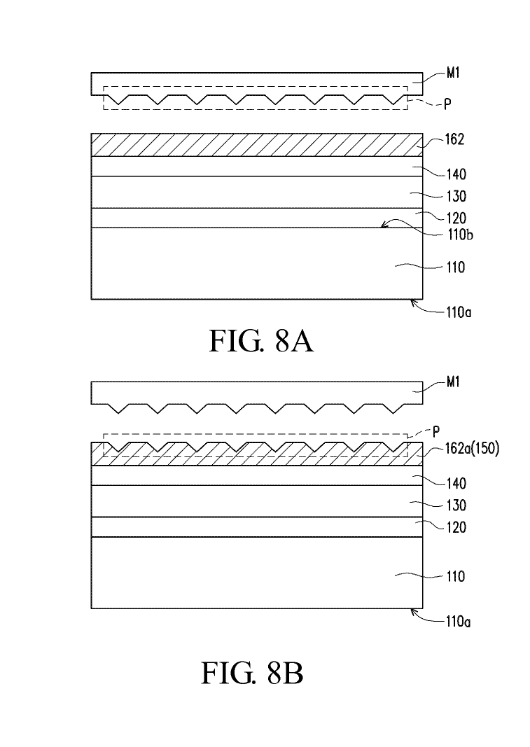

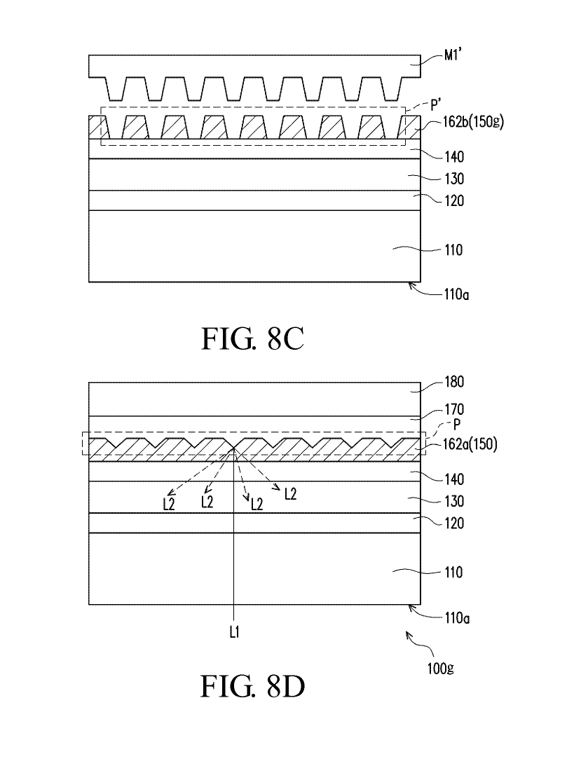

FIGS. 8A to 8D are schematic cross-sectional views illustrating a manufacturing process of a thin-film solar cell according to an embodiment of the present invention, in which FIG. 8C is a schematic cross-sectional view of forming a light reflecting structure having a texture structure according to another embodiment. Referring to FIG. 8A, firstly, a transparent substrate 110 is provided. The transparent substrate 110, which is a glass substrate for example, has a light incident surface 110a. Then, a first transparent conductive layer 120, a photovoltaic layer 130 and a second transparent conductive layer 140 are sequentially formed on a light exiting surface of the transparent substrate 110 opposite to the light incident surface 110a.

In this embodiment, the first transparent conductive layer 120 is formed on the transparent substrate 110. The first transparent conductive layer 120 may be formed through a sputtering process, a metal organic chemical vapor deposition (MOCVD) process or an evaporation process.

Still referring to FIG. 8A, in this embodiment, the photovoltaic layer 130 is formed on the first transparent conductive layer 120. The photovoltaic layer 130 is formed through, for example, a radio frequency plasma enhanced chemical vapor deposition (RF PECVD) process, a very high frequency plasma enhanced chemical vapor deposition (VHF PECVD) process or a microwave plasma enhanced chemical vapor deposition (MW PECVD) process.

After formation of the photovoltaic layer 130, the second transparent conductive layer 140 is formed on the photovoltaic layer 130, as shown in FIG. 8A. In this embodiment, the way in which the second transparent conductive layer 140 is formed is the same as way in which the first transparent conductive layer 120 is formed. Next, referring also to FIG. 8A, a reflective material layer 162 is formed on the second transparent conductive layer 140 entirely; i.e., the reflective material layer 162 covers the second transparent conductive layer 140 completely. Thereafter, a mold M1 having a texture pattern P is provided on the reflective material layer 162.

Afterwards, the mold M1 having the texture pattern P is mechanically impressed onto the reflective material layer 162, as shown in FIG. 8B. Then, the reflective material layer 162a is cured to form a light reflecting structure 150 having the texture structure P. That is, after the impressing with the mold M and the curing, the reflective material layer 162a having the texture structure P just serves as the light reflecting structure 150. Of course, in other embodiments, as shown in FIG. 8C, another kind of light reflecting structure 150g exposing portions of the second transparent conductive layer 140 may also be formed by impressing a mold M1′ having a texture pattern P′ onto the reflective material layer 162. That is, after the impressing with the mold M1′ and the curing, the reflective material layer 162b having the texture structure P′ and exposing portions of the second transparent conductive layer 140 just serves as the light reflecting structure 150. As can be known from above, in this embodiment, the light reflecting structures 150, 150g may be formed through the impression process, wherein the force applied in the mechanical impression process may depend on the configurations of the light reflecting structures 150, 150g.

Upon completion of the step shown in FIG. 8B, the mold M1 is removed and an adhesive layer 170 is applied on the light reflecting structure 150 to package a counter transparent substrate 180 and the transparent substrate 110 together, as shown in FIG. 8D. In this embodiment, the adhesive layer 170 is made of, for example, an adhesive such as ethylene vinyl acetate (EVA), polyvinyl butyral (PVB), poly olefin or polyurethane (PU). The counter transparent substrate 180 is, for example, a glass substrate. Here, the way of using the adhesive layer 170 to package the transparent substrate 110 and the counter transparent substrate 180 is well known to those of ordinary skill in the art, so no further description will be made thereon. Thus, fabrication of the thin-film solar cell 100g is substantially completed.

As shown in FIG. 8D, because the thin-film solar cell 100g of this embodiment comprises the light reflecting structure 150, the light beam L1 entering the thin-film solar cell 100g via the light incident surface 110a of the transparent substrate 110 sequentially passes through the transparent substrate 110, the first transparent conductive layer 120 and the photovoltaic layer 130, and a part of the light beam L1 unabsorbed by the photovoltaic layer 130 further passes through the second transparent conductive layer 140 to the reflective material layer 162a. Then, it becomes easier for the light beam L1 to be reflected by the texture structure P of the reflective material layer 162a and for the reflected light beam L2 to be scattered. This can prolong the light path of the light beam L2 in the photovoltaic layer 130 and, consequently, increase the opportunity for the light beam L2 to be absorbed by the photovoltaic layer 130, thus resulting in improved photoelectric conversion efficiency. Here, the texture structure P reflects and scatters the reflected light beam L2, and the light beam L2 is, for example, a red light, a near IR light or a far IR light.

In other words, by means of the reflective material layer 162a having the texture structure P that can affect the propagation direction of the light beam L1, the light beam L1 is reflected and scattered at the interface between the reflective material layer 162a and the second transparent conductive layer 140. Thus, the reflective material layer 162a can increase the opportunity for the light beam L1 to be reflected in the thin-film solar cell 100g. This can prolong the light path of the light beam L1 in the photovoltaic layer 130 and, consequently, increase the opportunity for the light beam to be absorbed by the photovoltaic layer 130. In other words, the thin-film solar cell 100g can effectively absorb the light beam L1 and convert it into electric energy, thus resulting in higher photoelectric conversion efficiency.

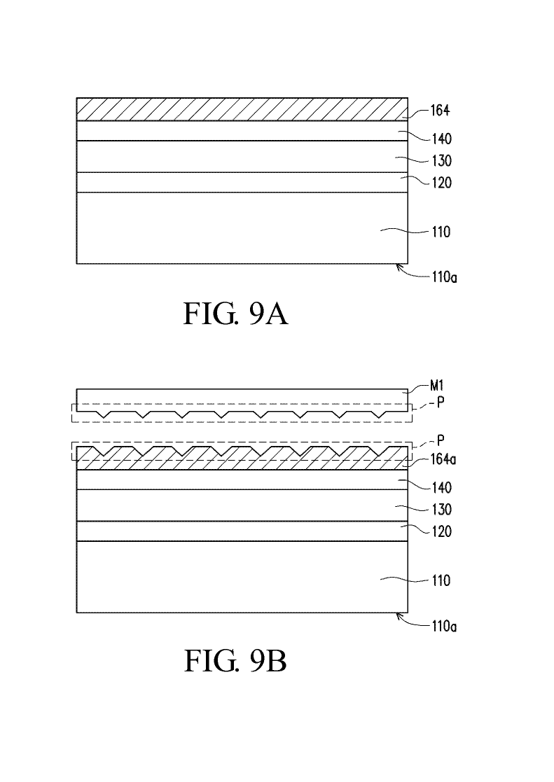

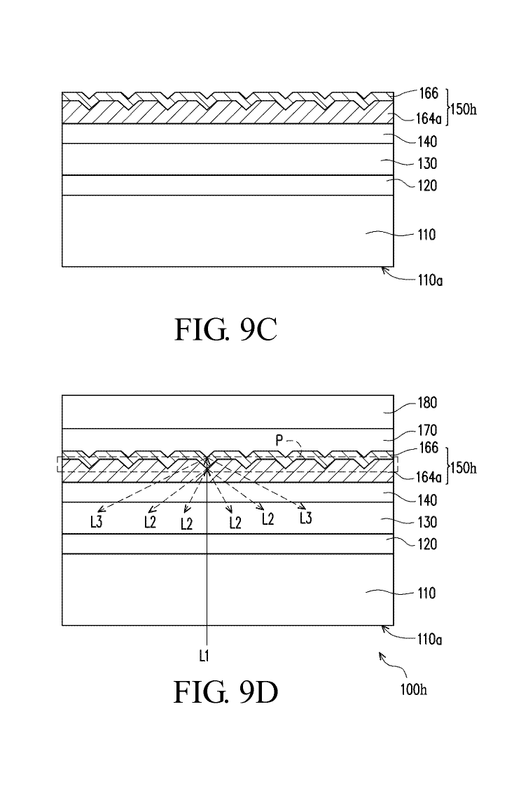

FIGS. 9A to 9D are schematic cross-sectional views illustrating a manufacturing process of a thin-film solar cell according to another embodiment of the present invention. The process of forming the thin-film solar cell 100h is similar to that of forming the thin-film solar cell 100g, and differences therebetween will be described below.

Referring to FIG. 9A, after the second transparent conductive layer 140 is formed on the photovoltaic layer 130, a transparent material layer 164 is formed on the second transparent conductive layer 140 entirely. Next, as shown in FIG. 9B, a mold M1 having a texture pattern P is impressed onto the transparent material layer 164, and then the transparent material layer 164a is cured to form the texture structure P on a surface of the transparent material layer 164a. Then, as shown in FIG. 9C, the mold M1 is removed and a reflective material layer 166 is formed on the transparent material layer 164a. The reflective material layer 166 is conformal to the transparent material layer 164a. Here, the reflective material layer 166 and the transparent material layer 164a conformal to each other can be viewed as a light reflecting structure 150h. Thereafter, as shown in FIG. 9D, the adhesive layer 170 is applied onto the light reflecting structure 150h to package the counter transparent substrate 180 and the transparent substrate 110 together, thus completing the fabrication of the thin-film solar cell 100h.

In this embodiment, the stack structure formed by the transparent material layer 164a and the conformal reflective material layer 166 thereon can be viewed as the light reflecting structure 150h, so when the light beam L1 propagates to the light reflecting structure 150h, the texture structure P on the surface of the transparent material layer 164a can also affect the propagation direction of the light beam L1 in such a way that the light beam L1 is reflected and scattered at the interface between the transparent material layer 164a and the second transparent conductive layer 140. Furthermore, a part of the light beam L1 that is not reflected and scattered by the texture structure P will further pass through the transparent material layer 164a and be reflected by the reflective material layer 166 as a light beam L3, thus prolonging the light paths of the light beams L2 and L3 in the photovoltaic layer 130. This can increase the opportunity for the light beams L2 and L3 to be absorbed by the photovoltaic layer 130 to improve overall photoelectric conversion efficiency. In other words, the thin-film solar cell 100h can effectively absorb the light beam L1 and convert it into electric energy, thus resulting in higher photoelectric conversion efficiency.

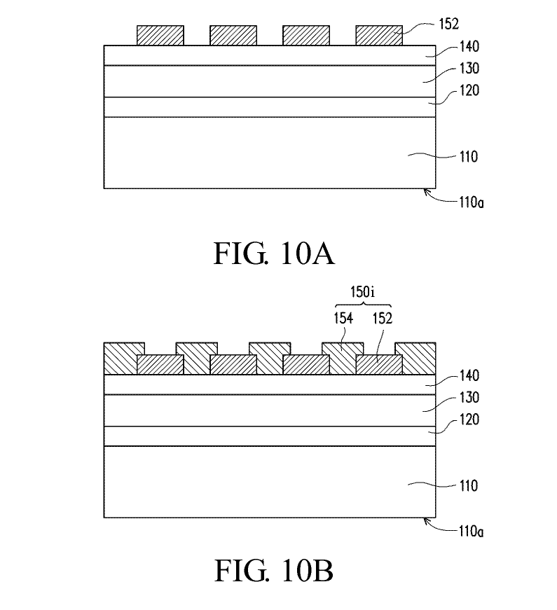

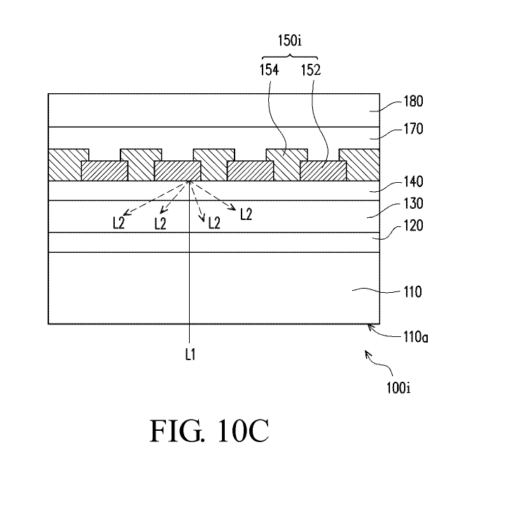

FIGS. 10A to 10C are schematic cross-sectional views illustrating a manufacturing process of a thin-film solar cell according to another embodiment of the present invention. The process of forming the thin-film solar cell 100i is similar to that of forming the thin-film solar cell 100g, and differences therebetween will be described below.

Referring to FIG. 10A, after the second transparent conductive layer 140 is formed on the photovoltaic layer 130, a first sub-pattern structure 152 exposing portions of the second transparent conductive layer 140 is imprinted on the second transparent conductive layer 140. Then, a second sub-pattern structure 154 is imprinted on the first sub-pattern structure 152. The second sub-pattern structure 154 at least partially overlaps the first sub-pattern structure 152 to form a light reflecting structure 150i, as shown in FIG. 10B. Thereafter, as shown in FIG. 10B, the adhesive layer 170 is applied onto the light reflecting structure 150i to package the counter transparent substrate 180 and the transparent substrate 110 together, thus completing the fabrication of the thin-film solar cell 100i.

It is worth noting that, in this embodiment, the patterned structure 150i is, for example, of a check form formed by orthogonal intersection of the first sub-pattern structure 152 and the second sub-pattern structure 154 as shown in FIG. 2A; a rhombus form formed by intersection of the first sub-pattern structure 152 and the second sub-pattern structure 154 at an angle as shown in FIG. 2B; a straight stripe form (shown in FIG. 2C), a regular or irregular stripe form (not shown) or a transverse stripe form (not shown) formed by parallel arrangement and partial overlapping between the first sub-pattern structure 152 and the second sub-pattern structure 154; or a mosaic form (shown in FIG. 2D) or a honeycomb form (not shown) formed through regular or irregular arrangement of the first sub-pattern structure 152 and the second sub-pattern structure 154. In other words, the arrangement and structures of the first sub-pattern structure 152 and the second sub-pattern structure 154 can be varied depending on the user's requirements; and what described above is only for illustration purpose but is not to limit the present invention.

In this embodiment, the stack structure formed by the first sub-pattern structure 152 and the second sub-pattern structure 154 can affect the propagation direction of the light beam L1 in such a way that the light beam L1 is reflected and scatted at the interface between the light reflecting structure 150i and the second transparent conductive layer 140 to form a light beam L2. This increases the opportunity for the light beam L1 to be reflected in the thin-film solar cell 100i and, consequently, prolongs the light path of the light beam L2 in the photovoltaic layer 130 so that the light beam L2 will be more likely be absorbed by the photovoltaic layer 130. In this way, the thin-film solar cell 100i can effectively absorb the light beam L1 and convert it into electric energy, thus resulting in higher photoelectric conversion efficiency.

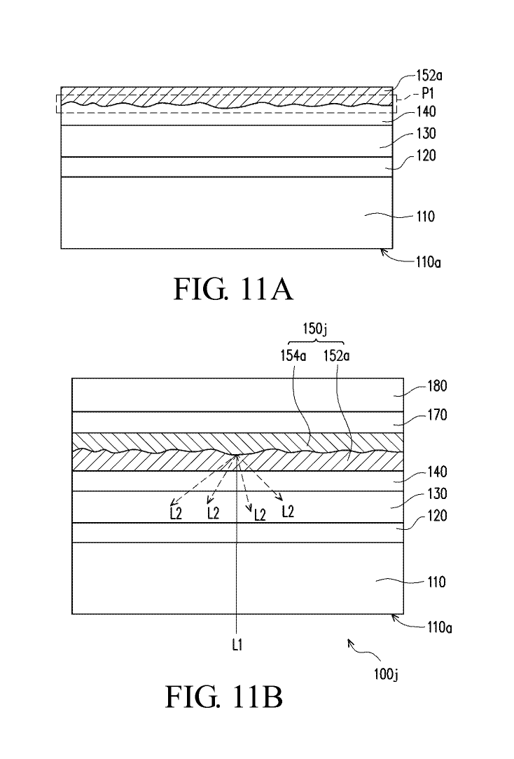

FIGS. 11A and 11B are schematic cross-sectional views illustrating a manufacturing process of a thin-film solar cell according to another embodiment of the present invention. The process of forming the thin-film solar cell 100j is similar to that of forming the thin-film solar cell 100i, and differences therebetween will be described below.

Referring to FIG. 11A, before impressing the first sub-pattern structure 152a on the second transparent conductive layer 140, a texture structure P1 is formed on the first sub-pattern structure 152a. The texture structure P1 is disposed on a surface where the first sub-pattern structure 152a makes contact with the second transparent conductive layer 140. Here, the first sub-pattern structure 152a covers the second transparent conductive layer 140 entirely. Then as shown in FIG. 11B, sequentially, the second sub-pattern structure 154a is imprinted on the first sub-pattern structure 152a and the adhesive layer 170 is applied onto the second sub-pattern structure 154a to package the counter transparent substrate 180 and the transparent substrate 110 together, thus completing the fabrication of the thin-film solar cell 100j. Here, the second sub-pattern structure 154a covers the first sub-pattern structure 152a entirely, and the stack structure formed by the first sub-pattern structure 152a and the second sub-pattern structure 154a may be viewed as a light reflecting structure 150j.

In this embodiment, the surface where the first sub-pattern structure 152a makes contact with the second transparent conductive layer 140 is a texture structure P1 which is, for example, a surface microstructure formed on the surface of the first sub-pattern structure 152a. Of course, in other embodiments not shown, the texture structure P1 may also be a surface microstructure formed on the surface of the second transparent conductive layer 140. Additionally, in an embodiment not shown, a surface where the second sub-pattern structure makes contact with the first sub-pattern structure may also be a texture structure, which may be a surface microstructure formed on either the first sub-pattern structure or the second sub-pattern structure, although the present invention is not limited thereto.

Because the surface where the first patterned structure 152a makes contact with the second transparent conductive layer 140 is the texture structure P1, it becomes easier for the light beam L1 propagating to the texture structure P1 to be reflected by the texture structure P1 and for the reflected light beam L2 to be scattered. This can prolong the light path of the light beam L2 in the photovoltaic layer 130 and, consequently, increase the opportunity for the light beam L2 to be absorbed by the photovoltaic layer 130, thus improving the overall photoelectric conversion efficiency. Furthermore, the part L2 of the light beam L1 can be reflected directly by the light reflecting structure 150j to the photovoltaic layer 130. In other words, the first sub-pattern structure 152a and the second sub-pattern structure 154a can affect the propagation direction of the light beam L1 in such a way that the light beam L1 is reflected and scattered by the surface where the first sub-pattern structure 152a makes contact with the second transparent conductive layer 140 or in such a way that the light beam L1 is reflected by the second patterned structure 154. In this way, the opportunity for the light beam L1 to be reflected in the thin-film solar cell 100j can be increased to prolong the light path of the light beam L1 in the photovoltaic layer 130 so that the light beam L1 will be more likely absorbed by the photovoltaic layer 130 to generate more electron-hole pairs. Therefore, the thin-film solar cell 100j can effectively enhance the utilization factor of the light beam L1 to improve the photoelectric conversion efficiency thereof.

It is worth noting that, in an embodiment not shown, the light reflecting structure may also be a poly-layer formed by a plurality of first polymer materials and a plurality of second polymer materials alternately arranged. The first polymer materials are, for example, hydroxyl acetoxylated polyethylene terephthalate (PET) or a copolymer of hydroxyl acetoxylated polyethylene terephthalate, and the second polymer materials are, for example, polyethylene naphthalate (PEN) or a copolymer of polyethylene naphthalate. However, the materials described above are only provided as examples, and materials that can have the light reflecting structure 150j reflect the light beam all fall within the scope of the present invention.

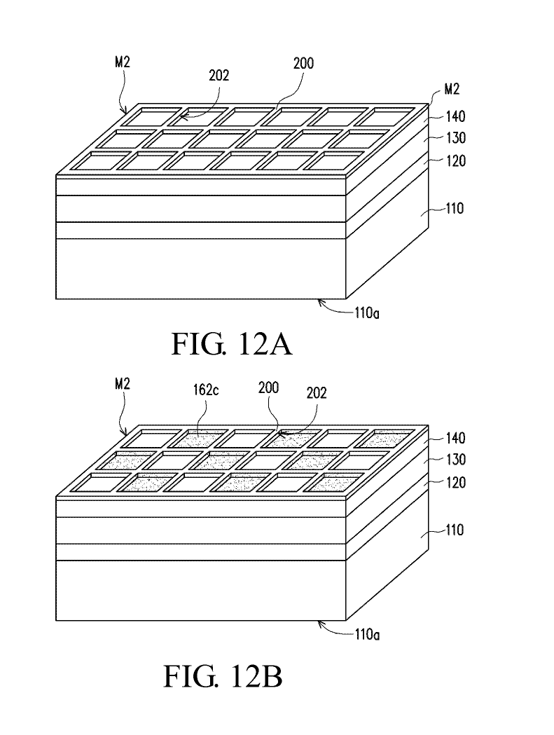

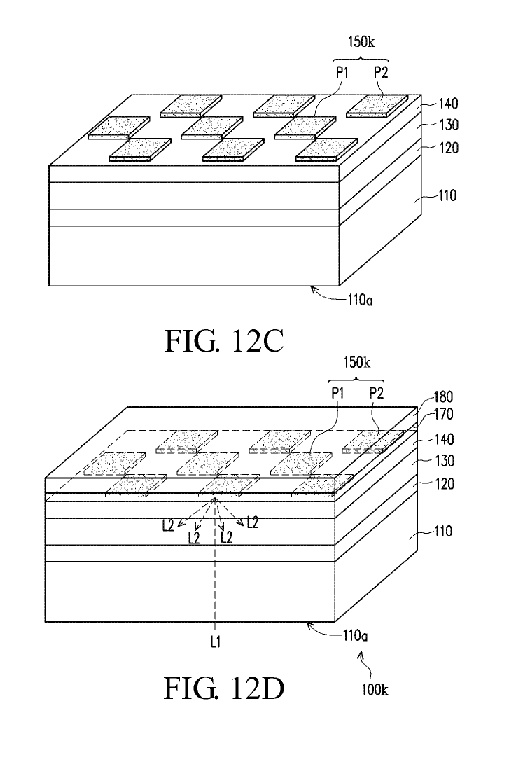

FIGS. 12A to 12D are schematic cross-sectional views illustrating a manufacturing process of a thin-film solar cell according to another embodiment of the present invention. The process of forming the thin-film solar cell 100k is similar to that of forming the thin-film solar cell 100g, and differences therebetween will be described below.

Referring to FIG. 12A, after the second transparent conductive layer 140 is formed, a mold M2 having a mesh pattern 200 is disposed on the second transparent conductive layer 140. The mesh pattern 200 has a plurality of openings 202 exposing the second transparent conductive layer 140. Next, as shown in FIG. 12B, a reflective material layer 162c is formed on the mold M2, with portions of the reflective material layer 162c being filled into the openings 202 to connect with the second transparent conductive layer 140. Next, as shown in FIG. 12C, the mold M2 is removed to form a light reflecting structure 150k having a texture structure P2. Afterwards, as shown in FIG. 12D, the adhesive layer 170 is applied onto the light reflecting structure 150k to package the counter transparent substrate 180 and the transparent substrate 110 together, thus completing the fabrication of the thin-film solar cell 100k.

In brief, this embodiment forms the light reflecting structure 150k through a mesh process. The reflective material layer 162c can be filled into the openings 202 randomly through the mesh pattern 200 to form on the second transparent conductive layer 140 the light reflecting structure 150k having the texture structure P2. Owing to the texture structure P2 of the light reflecting structure 150k, the opportunity for the light beam L1 to be reflected and scattered in thin-film solar cell 100k can get increased. This prolongs the light path of the light beam L2 in the photovoltaic layer 130 and, consequently, increases the opportunity for the light beam L2 to be absorbed by the photovoltaic layer 130 to generate more electron-hole pairs. In this way, the thin-film solar cell 100k can effectively enhance the utilization factor of the light beam L1, thus resulting in higher photoelectric conversion efficiency thereof.

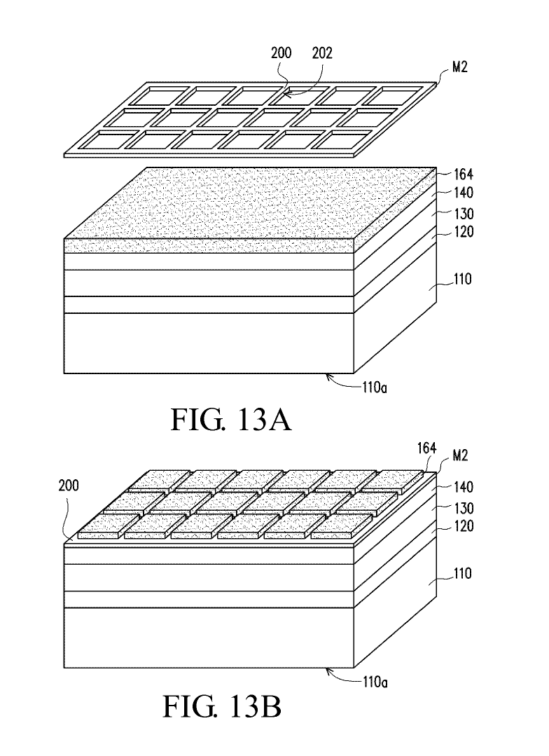

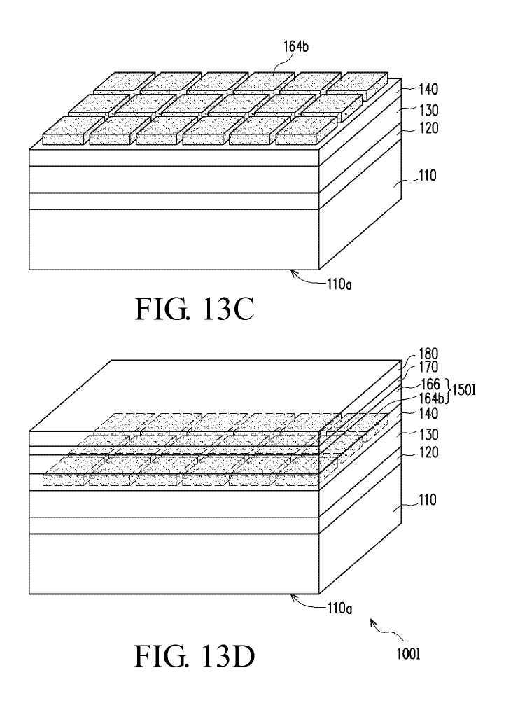

FIGS. 13A to 13D are schematic cross-sectional views illustrating a manufacturing process of a thin-film solar cell according to another embodiment of the present invention. The process of forming the thin-film solar cell 100l is similar to that of forming the thin-film solar cell 100k, and differences therebetween will be described below.

Referring to FIG. 13A, after the second transparent conductive layer 140 is formed, a transparent material layer 164 is formed on the second transparent conductive layer 140 entirely. Then, as shown in FIG. 13B, a mold M2 having the mesh pattern 200 is impressed onto the transparent material layer 164. Next, as shown in FIG. 13C, after curing of the transparent material layer 164b, the mold M2 is removed to form a mesh pattern 200 on the surface of the transparent material layer 164b. Afterwards, as shown in FIG. 13D, a reflective material layer 166 is formed on the transparent material layer 164b. The reflective material layer 166 covers the entire transparent material layer 164b and portions of the second transparent material layer 140. Here, the stack structure formed by the transparent material layer 164b and the reflective material layer 166 can be viewed as a light reflecting structure 150l. Then, as shown in FIG. 13D, the adhesive layer 170 is applied onto the light reflecting structure 150l to package the counter transparent substrate 180 and the transparent substrate 110 together, thus completing the fabrication of the thin-film solar cell 100l.

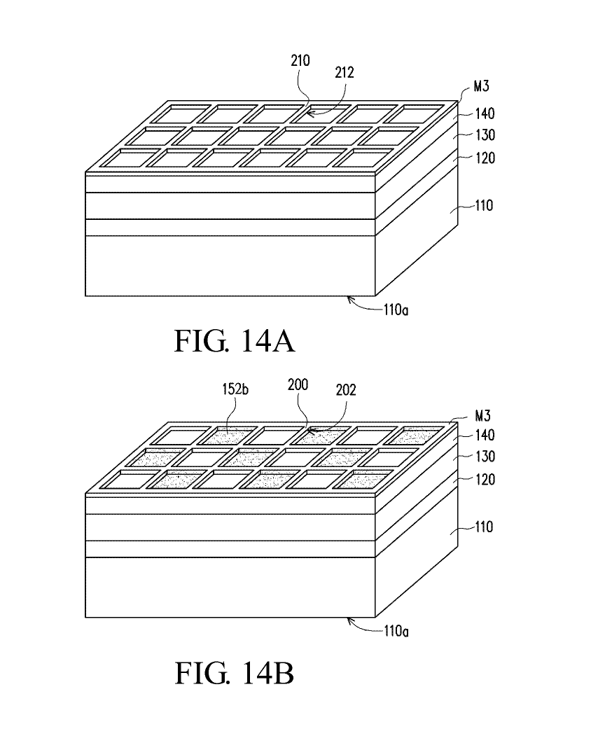

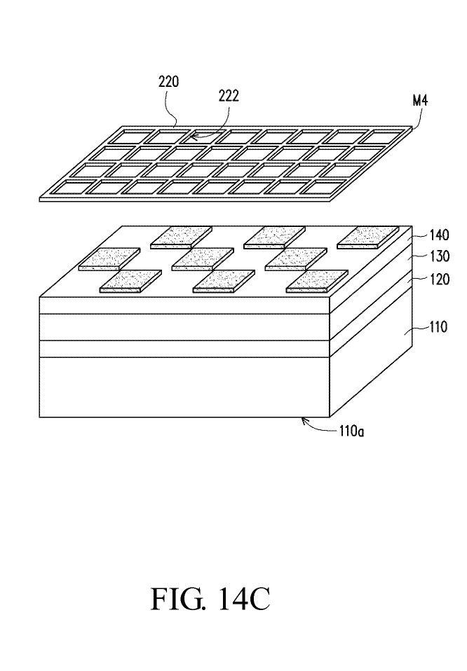

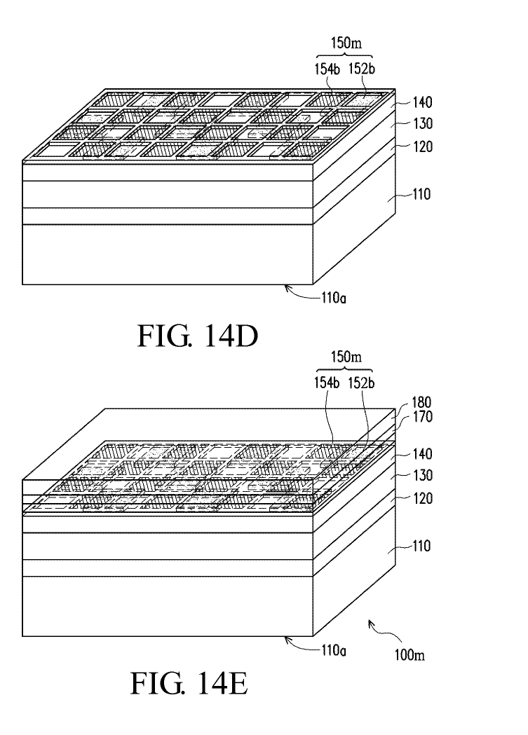

FIGS. 14A to 14E are schematic cross-sectional views illustrating a manufacturing process of a thin-film solar cell according to another embodiment of the present invention. The process of forming the thin-film solar cell 100m is similar to that of forming the thin-film solar cell 100k, and differences therebetween will be described below.

Referring to FIG. 14A, after the second transparent conductive layer 140 is formed, a first mold M3 having a first mesh pattern 210 is disposed on the second transparent conductive layer 140. The first mesh pattern 210 has a plurality of openings 212 exposing the second transparent conductive layer 140. Next, as shown in FIG. 14B, a first sub-pattern structure 152b is formed on the first mold M3, with the first sub-pattern structure 152b being connected with portions of the second transparent conductive layer 140. Next, as shown in FIG. 14C, after curing of the first sub-pattern structure 152b, the first mold M3 is removed and a second mold M4 having a second mesh pattern 220 is disposed on the first sub-pattern structure 152b. The second mesh pattern 220 has a plurality of second openings 222 that expose at least portions of the first openings 212. Thereafter, as shown in FIG. 14D, a second sub-pattern structure 154b is formed on the first sub-pattern structure 152b. The second sub-pattern structure 154b at least partially overlaps the first sub-pattern structure 152b to form a light reflecting structure 150m. Finally, as shown in FIG. 14E, the adhesive layer 170 is applied onto the light reflecting structure 150m to package the counter transparent substrate 180 and the transparent substrate 110 together, thus completing the fabrication of the thin-film solar cell 100m.

Of course, the aforesaid methods for manufacturing thin-film solar cells are only illustrated as examples, and some of the steps are common in the art. Depending on practical conditions, alterations, omissions or additions may be made on the steps by those skilled in the art to meet practical process requirements, which will not be further described herein. Furthermore, in other embodiments not shown, the aforesaid elements can be optionally selected by those skilled in the art, based on the descriptions of the aforesaid embodiments, to achieve the desired technical effect depending on practical requirements.

According to the above descriptions, the methods for manufacturing a thin-film solar cell of the present invention form a light reflecting structure having a texture structure on the second transparent conductive layer to increase the opportunity for the light beam to be reflected in the thin-film solar cell. This can prolong the light path of the light beam in the photovoltaic layer so that the light beam will be more likely absorbed by the photovoltaic layer to generate more electron-hole pairs. In other words, the methods for manufacturing a thin-film solar cell of the present invention can effectively enhance the utilization factor of the light beam to improve the photoelectric conversion efficiency of the resulting thin-film solar cell.

The above disclosure is related to the detailed technical contents and inventive features thereof. People skilled in this field may proceed with a variety of modifications and replacements based on the disclosures and suggestions of the invention as described without departing from the characteristics thereof. Nevertheless, although such modifications and replacements are not fully disclosed in the above descriptions, they have substantially been covered in the following claims as appended.

What is claimed is:

1. A thin-film solar cell, comprising:
a transparent substrate, having a light incident surface and a light exiting surface opposite to the light incident surface;
a first transparent conductive layer, being disposed on the light exiting surface of the transparent substrate;
a photovoltaic layer, being disposed on the first transparent conductive layer;
a second transparent conductive layer, being disposed on the photovoltaic layer; and
a light reflecting structure, being disposed on the second transparent conductive layer;
wherein a light beam enters the thin-film solar cell via the light incident surface, passes sequentially through the transparent substrate, the first transparent conductive layer, the photovoltaic layer and the second transparent conductive layer and then into the light reflecting structure, and the light reflecting structure reflects the light beam.

2. The thin-film solar cell as claimed in claim 1, wherein the light reflecting structure comprises a patterned structure having a first sub-pattern structure and a second sub-pattern structure, the first sub-pattern structure is disposed on the second transparent conductive layer and the second sub-pattern structure is disposed on the first sub-pattern structure, and the second sub-pattern structure at least partially overlaps the first sub-pattern structure.

3. The thin-film solar cell as claimed in claim 2, wherein a surface where the first sub-pattern structure makes contact with the second transparent conductive layer is a texture structure.

4. The thin-film solar cell as claimed in claim 2, wherein at least a surface where the second sub-pattern structure makes contact with the first sub-pattern structure is a texture structure.

5. The thin-film solar cell as claimed in claim 1, wherein the light reflecting structure is a light reflecting structure layer, and the light reflecting structure layer is integrally formed.

6. The thin-film solar cell as claimed in claim 5, wherein the light reflecting structure layer entirely or partially covers the second transparent conductive layer.

7. The thin-film solar cell as claimed in claim 6, wherein a surface where the light reflecting structure layer makes contact with the second transparent conductive layer is a texture structure.

8. A method for manufacturing a thin-film solar cell, comprising:
providing a transparent substrate;
forming a first transparent conductive layer on the transparent substrate;
forming a photovoltaic layer on the first transparent conductive layer;
forming a second transparent conductive layer on the photovoltaic layer; and
forming a light reflecting structure having a texture structure on the second transparent conductive layer.

9. The method for manufacturing a thin-film solar cell as claimed in claim 8, wherein the light reflecting structure is formed through one of an impression process and a mesh process.

10. The method for manufacturing a thin-film solar cell as claimed in claim 9, wherein the impression process comprises:
forming a reflective material layer on the second transparent conductive layer entirely; and
impressing a mold with a texture pattern onto the reflective material layer to form the light reflecting structure having the texture structure.

11. The method for manufacturing a thin-film solar cell as claimed in claim 9, wherein the impression process comprises:
forming a transparent material layer on the second transparent conductive layer entirely;
impressing a mold with a texture pattern onto the transparent material layer to form the texture structure on the surface of the transparent material layer; and
forming a reflective material layer on the transparent material layer.

12. The method for manufacturing a thin-film solar cell as claimed in claim 9, wherein the impression process comprises:
impressing a first sub-pattern structure on the second transparent conductive layer; and
impressing a second sub-pattern structure on the first sub-pattern structure;
wherein the second sub-pattern structure at least partially overlaps the first sub-pattern structure to form the light reflecting structure.

13. The method for manufacturing a thin-film solar cell as claimed in claim 9, wherein the mesh process comprises:
disposing a mold having a mesh pattern on the second transparent conductive layer, wherein the mesh pattern has a plurality of openings exposing the second transparent conductive layer;
forming a reflective material layer on the mold, wherein portions of the reflective material layer is filled into the openings to connect to the second transparent conductive layer; and
removing the mold to form the light reflecting structure having the texture structure.

14. The method for manufacturing a thin-film solar cell as claimed in claim 9, wherein the mesh process comprises:
forming a transparent material layer on the second transparent conductive layer entirely;
impressing a mold with a mesh pattern onto the transparent material layer to form the mesh pattern on a surface of the transparent material layer;
removing the mold; and
forming a reflective material layer on the transparent material layer.

15. The method for manufacturing a thin-film solar cell as claimed in claim 9, wherein the mesh process comprises:
disposing a first mold with a first mesh pattern on the second transparent conductive layer, wherein the first mesh pattern has a plurality of first openings exposing the second transparent conductive layer;
forming a first sub-pattern structure on the first mold, wherein the first sub-pattern structure connects with portions of the second transparent conductive layer;
disposing a second mold with a second mesh pattern on the first sub-pattern structure, wherein the second mesh pattern has a plurality of second openings exposing at least portions of the first openings; and
forming a second sub-pattern structure on the first sub-pattern structure, wherein the second sub-pattern structure at least partially overlaps the first sub-pattern structure to form the light reflecting structure.
